(19) United States
(12) Patent Application Publication
(10) Pub. No.: US 2015/0171041 A1
(43) Pub. Date: Jun. 18, 2015

(54) CHIP ELEMENT AND CHIP PACKAGE

(71) Applicant: MUTUAL-PAK TECHNOLOGY CO., LTD., Zhongli City (TW)

(72) Inventors: Po Ching CHEN, Zhongli City (TW); Lu-Chen HWAN, Zhongli City (TW)

(21) Appl. No.: 14/576,132

(22) Filed: Dec. 18, 2014

(30) Foreign Application Priority Data
Dec. 18, 2013 (TW) 102146859

(51) Int. Cl. H01L 23/00; G06K 9/00

(52) U.S. Cl. CPC H01L 24/16; G06K 9/0002; H01L 2224/13147; H01L 2224/13611; H01L 2224/13639; H01L 2224/13644; H01L 2224/1369; H01L 2224/11821; H01L 2224/11823; H01L 2224/11825; H01L 2224/13693; H01L 2924/01006; H01L 2224/16113; H01L 2224/16225

(57) ABSTRACT

A chip package of the present invention including a substrate, a chip, at least one electrical connecting element and a solder layer is provided. The substrate has at least one contact. The chip is disposed on the substrate and has at least one pad. The electrical connecting element includes a copper bump and an anti-oxidation layer. The copper bump is disposed on the pad. The anti-oxidation layer is disposed on at least part of an outside surface of the copper bump and the outside surface of the copper bump is not connected to the pad. The solder layer is disposed between the copper bump and the contact. The pad is electrically connected to the contact through the electrical connecting element and solder layer. In addition, a chip element of the present invention is also provided.

### CROSS REFERENCE TO RELATED APPLICATIONS

This application is based on and claims the benefit of priority from Taiwan Patent Application 102146859 filed on Dec. 18, 2013, which is incorporated herein by reference and assigned to the assignee herein.

### FIELD OF THE INVENTION

The present invention relates to a chip element and in particular, to a chip package.

### DESCRIPTION OF THE PRIOR ART

In the semiconductor industry, the manufacture of integrated circuits (IC) can be mainly divided into three stages: IC design, IC process, and IC package.

During the IC process, a chip is completed through the steps of wafer process, IC formation, wafer sawing, etc. The wafer has an active surface where a plurality of active elements are disposed. After the IC inside the wafer has been completed, a plurality of pads are further disposed on the active surface of the wafer. Accordingly, the chip eventually formed after wafer sawing can be electrically connected to a carrier through the pads. The carrier is, for example, a leadframe or a substrate. The pads of the chip can be electrically connected to a plurality of contacts of the carrier by means of wire bonding technology or flip-chip bonding technology such that a chip package is formed.

As for the flip-chip bonding technology, a plurality of conductive bumps are firstly formed on the plurality of pads disposed on the active surface of the wafer, respectively. After the wafer is sawed, the active surface of the chip faces the substrate and the chip is disposed on the substrate. The pads of the chip are electrically connected to the contacts of the substrate, respectively, through the conductive bumps. Since the conductive bumps are usually arranged on the active surface of the chip in an area array, the flip-chip bonding technology can be applied to the chip packages with high contact counts and high contact densities. In addition, in comparison with the wire bonding technology, the flip-chip bonding technology can enhance the electrical performance of the chip package formed by means of it since each of the conductive bumps can provide a shorter electrical transmission path between the chip and the substrate.

However, the material of the conductive bump is usually gold or tin-lead alloy. If the material of the conductive bump is gold, the chip and the substrate are usually connected by means of thermal compression that results in inferior connecting strength between the chip and the substrate and higher cost of gold. It should be mentioned that, if the material of the conductive bump is gold, soldering with soldering tin as solder cannot be used to electrically connect the gold bump and the contact of the substrate, since the tin of the soldering tin would completely replace the gold of the gold bump eventually. If the material of the conductive bump is tin-lead alloy, the pitch between the conductive bumps is larger and the electric conductivity and thermal conductivity of the conductive bump are inferior.

### SUMMARY OF THE INVENTION

The purpose of the present invention is to provide a chip package, wherein a copper bump with an anti-oxidation layer disposed on part of an outside surface thereof is used to electrically connect a chip and a substrate.

The purpose of the present invention is to provide a chip element including a copper bump with an anti-oxidation layer disposed on an outside surface thereof.

The present invention provides a chip package, comprising a substrate, a chip, at least one electrical connecting element and a solder layer. The substrate has at least one contact. The chip is disposed on the substrate and has at least one pad. The at least one electrical connecting element comprises a copper bump and an anti-oxidation layer. The copper bump is disposed on the pad. The anti-oxidation layer is disposed on at least part of an outside surface of the copper bump and the outside surface of the copper bump is not connected to the pad. The solder layer is disposed between the copper bump and the contact. The pad is electrically connected to the contact through the electrical connecting element and the solder layer.

In an embodiment of the present invention, the material of the anti-oxidation layer is tin, gold, silver, or organic solderability preservative (OSP).

In an embodiment of the present invention, the anti-oxidation layer is formed by chemical plating, immersion, or spray coating.

In an embodiment of the present invention, the chip is a fingerprint identification chip and has a two-dimensional sensing area, and the substrate has a through opening corresponding to the two-dimensional sensing area.

In an embodiment of the present invention, the chip package further comprises a protective layer disposed on the two-dimensional sensing area. In addition, the material of the protective layer may comprise nanodiamond.

In an embodiment of the present invention, the substrate further has at least one stress-releasing hole connected to a corner of the through opening.

The present invention further provides a chip element comprising a chip and at least one electrical connecting element. The chip has at least one pad. The at least one electrical connecting element comprises a copper bump and an anti-oxidation layer. The copper bump is disposed on the pad. The anti-oxidation layer is disposed on an outside surface of the copper bump and the outside surface of the copper bump is not connected to the pad.

In an embodiment of the present invention, the material of the anti-oxidation layer is tin, gold, silver, or organic solderability preservative.

In an embodiment of the present invention, the anti-oxidation layer is formed by chemical plating, immersion, or spray coating.

In an embodiment of the present invention, the chip is a fingerprint identification chip and has a two-dimensional sensing area.

In comparison with the gold bumps used in prior art, the copper bumps of the chip element or the chip package in one embodiment are more cost saving, and the connecting strength between the chip and the substrate of the chip package by means of soldering (with tin as the common solder material) is superior. Furthermore, in comparison with the tin-lead bumps used in prior art, the copper bumps in one embodiment of the present invention have superior electric conductivity and thermal conductivity, and the pitch between the copper bumps may be smaller. In addition, during the manufacture of the chip element or the chip package in one embodiment of the present invention, the anti-oxidation layer is disposed on the outside surface of the copper bump which is not connected to the pad, and thus the copper bump is less likely to be oxidized during the manufacture of the chip element or the chip package.

The following description, the appended claims, and the embodiments of the present invention further illustrate the features and advantages of the present invention.

### BRIEF DESCRIPTION OF THE DRAWINGS

FIG. 1A is a schematic top view of a chip package of a first embodiment of the present invention.

FIG. 1B is a schematic cross-section view of the chip package of FIG. 1A along a line I-I.

FIG. 2 is a schematic cross-section view of a chip package of a second embodiment of the present invention.

FIG. 3A is a schematic cross-section view of a chip package of a third embodiment of the present invention.

FIG. 3B is a schematic top view of a substrate of FIG. 3A.

### DETAILED DESCRIPTION OF THE EMBODIMENTS

### First Embodiment

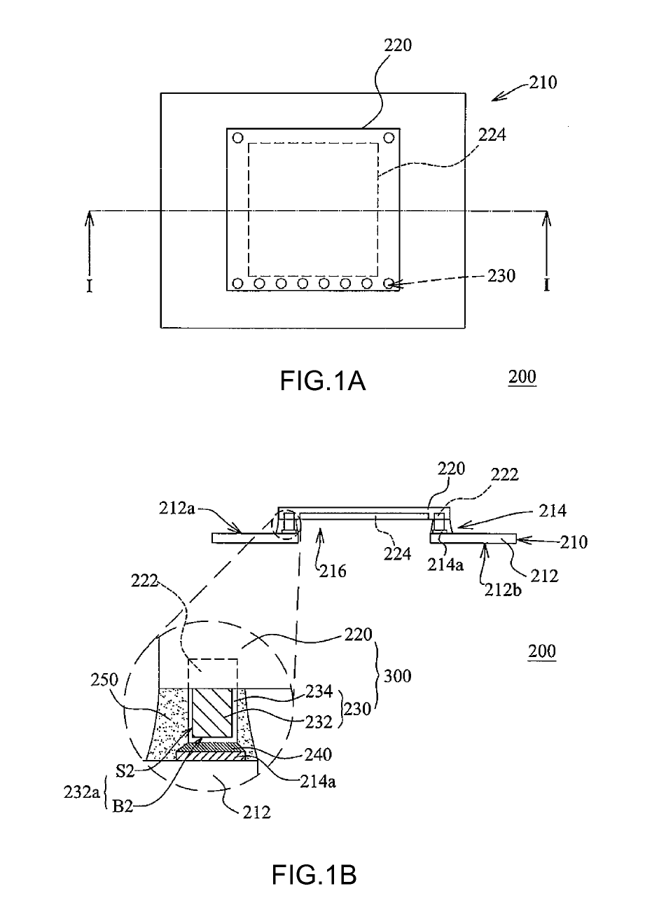

FIG. 1A is a schematic top view of a chip package of a first embodiment of the present invention. FIG. 1B is a schematic cross-section view of the chip package of FIG. 1A along a line I-I. Referring to FIG. 1A and FIG. 1B, a chip package 200 of the present embodiment includes a substrate 210, a chip 220, at least one electrical connecting element 230 (FIG. 1A and FIG. 1B schematically show multiple electrical connecting elements 230), and a solder layer 240. The substrate 210 includes a dielectric layer 212 and at least one circuit layer 214 (one circuit layer is schematically shown in FIG. 1B and omitted in FIG. 1A) having at least one contact 214a (FIG. 1B schematically shows multiple contacts 214a). The material of the dielectric layer 212 may be glass, polyimide (PI), or other suitable dielectric materials. The circuit layer 214 is disposed on a surface 212a of the dielectric layer 212. The circuit layer 214 of this embodiment may include other circuits in addition to the contacts 214a, which are not shown in the figures. In addition, in another embodiment, the substrate 210 may include another circuit layer disposed on another surface 212b of the dielectric layer 212, which is not shown in the figures.

The chip 220 is disposed on the surface 212a of the dielectric layer 212 of the substrate 210 and has at least one pad 222 (multiple pads 222 are schematically shown in FIG. 1B and omitted in FIG. 1A). In this embodiment, the chip 220 may be a fingerprint identification chip and has a two-dimensional sensing area 224. As for positional relations, the two-dimensional sensing area 224 of the chip 220 corresponds to a through opening 216 of the substrate 210. It should be mentioned that, a passivation layer (that exposes part of each of the pads 222 and the two-dimensional sensing area 224) may be disposed on a surface (i.e., the active surface) of the chip 220 where the pads 222 are disposed. An under bump metal layer (UBM layer) may be disposed on each of the pads 222 exposed by the passivation layer. However, the passivation layer and the UBM layer are not shown in the figures.

Each of the electrical connecting elements 230 includes a copper bump 232 and an anti-oxidation layer 234. For each of the electrical connecting elements 230, the copper bump 232 is disposed on one of the pads 222 and the anti-oxidation layer 234 is disposed on an outside surface 232a of the copper bump 232, wherein the outside surface 232a of the copper bump 232 is not connected to the pad 222 where the copper bump 232 is disposed. The material of each of the anti-oxidation layers 234 in this embodiment is tin or silver. If the material of each of the anti-oxidation layers 234 is tin, each of the anti-oxidation layers 234 may be formed by means of chemical plating or spray coating. If the material of each of the anti-oxidation layers 234 is silver, each of the anti-oxidation layers 234 may be formed by means of chemical plating. The chip 220 and the electrical connecting elements 230 may be regarded as a chip element 300, and an underfill 250 may be disposed between the chip 220 and the substrate 210 to cover and protect the electrical connecting elements 230.

The solder layer 240 is disposed between each of the copper bumps 232 and the corresponding contact 214a. Each of the pads 222 is electrically connected to one of the contacts 214a through one of the electrical connecting elements 230 and the solder layer 240. It should be mentioned that, if the material of each of the anti-oxidation layers 234 is tin and the material of the solder layer 240 is tin, the connecting boundary between a part of each of the anti-oxidation layers 234 on a bottom surface part B2 of the outside surface 232a of the corresponding copper bump 232 and the solder layer 240 may be less obvious. However, on a side surface part S2 of the outside surface 232a of each of the copper bumps 232 (i.e., a part of the outside surface 232a of each of the copper bumps 232 not used to be connected to the corresponding pad 222 and the corresponding contact 214a), the existence of the corresponding anti-oxidation layer 234 can be obviously observed. If the material of each of the anti-oxidation layers 234 is silver, the connecting boundary between each of the anti-oxidation layers 234 and the solder layer 240 would be more obvious. Therefore, in order to schematically depict the above situation in this embodiment, the connecting boundary between each of the anti-oxidation layers 234 and the solder layer 240 in FIG. 1B is shown as a dashed line.

The manufacture of the chip package of this embodiment is briefly described below. Before the wafer (not shown) is sawed to form each of the chips 220, the copper bumps 232 are respectively formed on the pads 222 of the wafer and each of the anti-oxidation layers 234 is formed on the exposing outside surface 232a of the corresponding copper bump 232 so that the plurality of the electrical connecting elements 230 is formed. Subsequently, the wafer where the electrical connecting elements 230 are disposed is sawed so that each of the singulated chip elements 300 (including the corresponding chip 220 and the corresponding electrical connecting elements 230) is formed. Subsequently, the solder layer 240 is formed on all of the contacts 214a of an array substrate (not shown). The chip elements 300 are then respectively disposed on a plurality of predetermined areas of the array substrate by means of flip-chip bonding technology and soldering technology so that the pads 222 of the chips 220 are electrically connected to the contacts 214a of the array substrate through the solder layer 240 and the electrical connecting elements 230. Subsequently, the underfill 250 may be formed between the chips 220 and the array substrate to cover and protect the electrical connecting elements 230. Finally, the array substrate is sawed to separate the plurality of substrates 210 to form each of the chip packages 200 including the corresponding chip element 300 and the corresponding substrate 210.

In comparison with the gold bumps used in prior art, the copper bumps 232 of the chip package 200 in this embodiment are more cost saving, and the connecting strength between the chip 220 and the substrate 210 by means of soldering (with tin as the common solder material) is superior. Furthermore, in comparison with the tin-lead bumps used in prior art, the copper bumps 232 have superior electric conductivity and thermal conductivity, and the pitch between the copper bumps 232 may be smaller. In addition, during the manufacture of the chip element 300 or the chip package 200, the anti-oxidation layer 234 is disposed on the outside surface 232a of the copper bump 232 which is not connected to the pad 222, and thus the copper bump 232 is less likely to be oxidized during the manufacture of the chip element 300 or the chip package 200.

### Second Embodiment

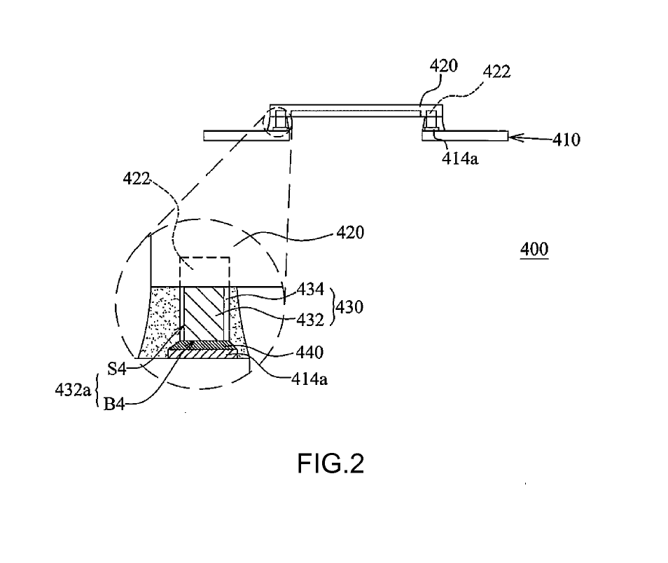

FIG. 2 is a schematic cross-section view of a chip package of a second embodiment of the present invention. Referring to FIG. 2, the difference between the chip package 400 of this embodiment and the chip package 200 of the first embodiment is that the material of the anti-oxidation layers 434 of the chip package 400 of this embodiment is gold or organic solderability preservative (OSP). If the material of each of the anti-oxidation layers 434 is gold, each of the anti-oxidation layers 434 may be formed by means of chemical plating. If the material of each of the anti-oxidation layers 434 is insulated OSP, each of the anti-oxidation layers 434 may be formed by immersion.

It should be mentioned that, if the material of each of the anti-oxidation layers 434 is gold or OSP and the material of the solder layer 440 is tin, for each of the electrical connecting elements 430, the anti-oxidation layer 434 is usually only on a side surface part S4 of the outside surface 432a of the copper bump 432 (i.e., a part of the outside surface 432a of each of the copper bumps 432 not used to be connected to the corresponding pad 422 and the corresponding contact 414a). It should also be mentioned that, before the chip 420 and the substrate 410 is connected, the anti-oxidation layer 434 of each of the electrical connecting elements 430 is formed on the entire outside surface 432a of the copper bump 432 not connected to the corresponding pad 422. However, after the chip 420 and the substrate 410 is connected, for each of the electrical connecting elements 430, the solder layer 440 such as tin usually replaces or removes a part of the anti-oxidation layer 434 on a bottom surface part B4 of the outside surface 432a of the copper bump 432 so that the remaining anti-oxidation layer 434 is usually only on the side surface part S4 of the outside surface 432a of the copper bump 432.

### Third Embodiment

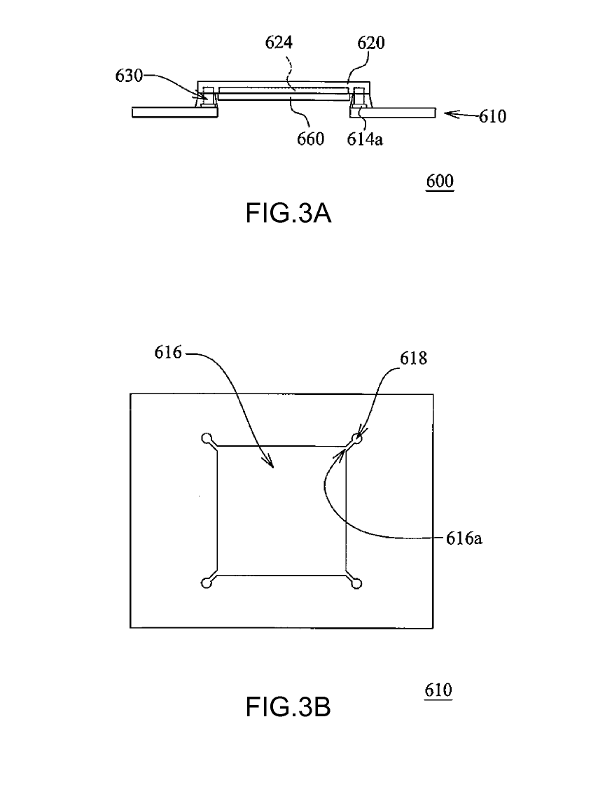

FIG. 3A is a schematic cross-section view of a chip package of a third embodiment of the present invention. FIG. 3B is a schematic top view of a substrate of FIG. 3A. Referring to FIG. 3A and FIG. 3B, the difference between the chip package 600 of this embodiment and the chip package 200 of the first embodiment is that the chip package 600 of this embodiment further includes a protective layer 660 disposed on the two-dimensional sensing area 624 of the chip 620 and the substrate 610 further has at least one stress-releasing hole 618 (FIG. 3B schematically shows multiple stress-releasing holes 618). The material of the protective layer 660 may include nanodiamond which is water-resistant and stain-resistant.

Each of the stress-releasing holes 618 is connected to a corner 616a of the through opening 616. In this embodiment, the through opening 616 shown in FIG. 3B is, for example, rectangular and the four corners 616a thereof are usually the stress concentration areas. Four stress-releasing holes 618 is respectively connected to the four corners 616a of the through opening 616 so that the substrate 610 maintains the expected flatness without warping too much after the electrical connecting elements 630 are respectively soldered to the contacts 614a (not shown in FIG. 3B) of the substrate 610 through the solder layer (not shown) under high temperature (if the solder layer is tin, the soldering temperature is approximately 200° C.).

The protective layer including nanodiamond and the stress-releasing holes may also be applied in the second embodiment, and the details are not repeated here.

The chip element and the chip package of one embodiment of the present invention have one of the following advantages or another advantage. In comparison with the gold bumps used in prior art, the copper bumps of the chip element or the chip package in one embodiment are more cost saving, and the connecting strength between the chip and the substrate of the chip package by means of soldering (with tin as the common solder material) is superior. Furthermore, in comparison with the tin-lead bumps used in prior art, the copper bumps in one embodiment of the present invention have superior electric conductivity and thermal conductivity, and the pitch between the copper bumps may be smaller. In addition, during the manufacture of the chip element or the chip package in one embodiment of the present invention, the anti-oxidation layer is disposed on the outside surface of the copper bump which is not connected to the pad, and thus the copper bump is less likely to be oxidized during the manufacture of the chip element or the chip package.

The foregoing detailed description of the embodiments is used to further clearly describe the features and spirit of the present invention. The foregoing description for each embodiment is not intended to limit the scope of the present invention. All kinds of modifications made to the foregoing embodiments and equivalent arrangements should fall within the protected scope of the present invention. Hence, the scope of the present invention should be explained most widely according to the claims described thereafter in connection with the detailed description, and should cover all the possibly equivalent variations and equivalent arrangements.

1. A chip package, comprising:
a substrate, having at least one contact;
a chip, disposed on the substrate and having at least one pad;
at least one electrical connecting element, comprising:
a copper bump, disposed on the pad; and
an anti-oxidation layer, disposed on at least part of an outside surface of the copper bump, wherein the outside surface of the copper bump is not connected to the pad; and
a solder layer, disposed between the copper bump and the contact, wherein the pad is electrically connected to the contact through the electrical connecting element and the solder layer.

2. The chip package as claimed in claim 1, wherein the material of the anti-oxidation layer is tin, gold, silver, or organic solderability preservative.

3. The chip package as claimed in claim 1, wherein the anti-oxidation layer is formed by chemical plating, immersion, or spray coating.

4. The chip package as claimed in claim 1, wherein the chip is a fingerprint identification chip and has a two-dimensional sensing area, and the substrate has a through opening corresponding to the two-dimensional sensing area.

5. The chip package as claimed in claim 4, further comprising a protective layer disposed on the two-dimensional sensing area.

6. The chip package as claimed in claim 5, wherein the material of the protective layer comprises nanodiamond.

7. The chip package as claimed in claim 4, wherein the substrate further has at least one stress-releasing hole connected to a corner of the through opening.

8. A chip element, comprising:
a chip, having at least one pad; and
at least one electrical connecting element, comprising:
a copper bump, disposed on the pad; and
an anti-oxidation layer, disposed on an outside surface of the copper bump, wherein the outside surface of the copper bump is not connected to the pad.

9. The chip element as claimed in claim 8, wherein the material of the anti-oxidation layer is tin, gold, silver, or organic solderability preservative.

10. The chip element as claimed in claim 8, wherein the anti-oxidation layer is formed by chemical plating, immersion, or spray coating.

11. The chip element as claimed in claim 8, wherein the chip is a fingerprint identification chip and has a two-dimensional sensing area.
